(19) United States
(12) Patent Application Publication
(10) Pub. No.: US 2021/0234535 A1
(43) Pub. Date: Jul. 29, 2021

(54) FILTERING METHOD AND DEVICE OF FILTER, FILTER AND STORAGE MEDIUM

(71) Applicant: Radiawave Technologies Co., Ltd., Shenzhen (CN)

(72) Inventors: Liuan ZHANG, Shenzhen (CN); Haigang FENG, Shenzhen (CN); Yulin TAN, Shenzhen (CN); Ning ZHANG, Shenzhen (CN); Jon Sweat DUSTER, Beaverton, OR (US)

(21) Appl. No.: 17/230,107

(22) Filed: Apr. 14, 2021

Related U.S. Application Data
(63) Continuation of application No. PCT/CN2019/111550, filed on Oct. 17, 2019.

(30) Foreign Application Priority Data
Oct. 17, 2018 (CN) 201811212097.7

(51) Int. Cl. H03H 17/02

(52) U.S. Cl. CPC H03H 17/02

(57) ABSTRACT

The present application discloses a filtering method and a filtering device of a filter, a filter and a storage medium. The method includes: obtaining a clock input signal and a clock output signal and comparing them, and determining a phase relationship between the clock input signal and the clock output signal according to a comparison result; determining a decimal deviation factor according to the phase relationship in determining that the phase relationship meets a preset condition; and filtering a sample input signal according to the decimal deviation factor to obtain a filtered sample output signal. The present application can obtain an accurate decimal deviation factor, by obtaining the phase relationship between the clock input signal and the clock output signal, in determining that the phase relationship meets a preset condition, and can adjust the sample input signal according to the decimal deviation factor to obtain a smooth sample output signal.

### CROSS-REFERENCE TO RELATED APPLICATION

The present application is a continuation application of International Application No. PCT/CN2019/111550, filed on Oct. 17, 2019, which claims priority to Chinese patent application No. 201811212097.7, filed on Oct. 17, 2018 and titled “Filtering Method and Device of Filter, Filter and Storage Medium”. The disclosures of the aforementioned applications are hereby incorporated by reference in their entireties.

### TECHNICAL FIELD

The present application relates to the technical field of filters, and particularly relates to a filtering method of a filter, a device of a filter, a filter, and a storage medium.

### BACKGROUND

In the related art, Chinese patent application No. 201110208518.0 discloses a universal rate down-conversion device, which mainly relates to a function that interpolation filtering is performed first and then decimation is performed, but does not mention how to ensure a high dynamic range of the farrow filter. Chinese patent application No. 201110325742.8 also does not provide a method to ensure a high dynamic range of the farrow filter. Chinese patent application No. 201210072562.8 discloses a filtering structure of a decimal delay digital filter, but also does not provide an implementation method to ensure a high dynamic range of the farrow filter. The farrow filter can generally achieve a dynamic range of 60 db, which cannot satisfy situations requiring such as a high dynamic voice.

### SUMMARY

The main purpose of the present application is to provide a filtering method of a filter, a device of filter, a filter, and a storage medium, aiming to achieve filtering of a high dynamic range.

In order to implement the above objective, the present application provides a filtering method of a filter, including the following steps:

obtaining a clock input signal and a clock output signal input by a farrow filter;

comparing the clock input signal with the clock output signal, and determining a phase relationship between the clock input signal and the clock output signal according to a comparison result;

determining a decimal deviation factor according to the phase relationship in determining that the phase relationship meets a preset condition; and

obtaining a sample input signal input by the farrow filter, and filtering the sample input signal according to the decimal deviation factor to obtain a filtered sample output signal.

Optionally, the comparing the clock input signal with the clock output signal, and determining a phase relationship between the clock input signal and the clock output signal according to a comparison result, comprises:

obtaining a ratio value of the clock input signal to the clock output signal, and determining unit precision values of the clock input signal and the clock output signal according to the ratio value and the clock output signal;

determining the phase relationship between the clock input signal and the clock output signal according to the unit precision values.

Optionally, the determining the phase relationship between the clock input signal and the clock output signal according to the unit precision values, comprises:

calculating an adjustment unit precision to left-right align the clock output signal to the clock input signal according to the unit precision values, and determining the phase relationship between the clock input signal and the clock output signal through a fast clock signal, a clock period of the fast clock being less than the adjustment unit precision.

Optionally, the determining a decimal deviation factor according to the phase relationship in determining that the phase relationship meets a preset condition, comprises:

obtaining a sample input clock period of the clock input signal and a sample output clock period of the clock input signal in determining that the phase relationship meets the preset condition;

in determining that the sample input clock period is greater than the sample output clock period, obtaining a data input sequence, putting the data input sequence and the phase relationship into a first preset formula for calculation to obtain a data output sequence, and putting the data input sequence, the phase relationship and the data output sequence into a second preset formula for calculation to obtain the decimal deviation factor; or

in determining that the sample input clock period is less than the sample output clock period, obtaining the data input sequence, putting a input data sequence and the phase relationship into a third preset formula for calculation to obtain a data output sequence, and putting the data input sequence, the phase relationship and the data output sequence into a fourth preset formula for calculation to obtain the decimal deviation factor;

the first preset formula is:

mₖ=int[k*Tₒ/Tᵢ];

k represents the data input sequence, Tₒ/Tᵢ represents the phase relationship, mₖ represents the data output sequence;

wherein, the second preset formula is:

μ=k*Tₒ/Tᵢ−mₖ;

μ represents the decimal deviation factor;

the third preset formula is:

mₖ=int[k*Tᵢ/Tₒ], Tᵢ/Tₒ represents the phase relationship;

the fourth preset formula is:

μ=k*Tᵢ/Tₒ−mₖ.

Optionally, the obtaining a sample input signal input by the farrow filter, and filtering the sample input signal according to the decimal deviation factor to obtain a filtered sample output signal, comprises:

obtaining the sample input signal input by the farrow filter, extracting a serial number identifier of a sequence in the sample input signal, and interpolating the sample input signal by an interpolation algorithm of a fifth preset formula according to the serial number identifier of the sequence, the data input sequence and the decimal deviation factor to obtain the output signal after being interpolated;

wherein, the fifth preset formula is:

$$P ( n ) = [ k ( n - ( - 1 ) ) k ( n - 0 ) k ( n - 1 ) k ( n - 2 ) ] * \vert \begin{matrix}- \frac{1}{6} & \frac{1}{2} & - \frac{1}{3} & 0 \\ \frac{1}{2} & - 1 & - \frac{1}{2} & 1 \\ - \frac{1}{2} & \frac{1}{2} & 1 & 0 \\ \frac{1}{6} & 0 & - \frac{1}{6} & 0\end{matrix} \vert * {[ {μ}^{3} {μ}^{2} μ 1 ]}^{′} ;$$

P(n) represents the sample output signal, and n represents a serial number identifier of a current input sequence of the farrow filter.

Optionally, the obtaining a clock input signal and a clock output signal comprises:

receiving a clock signal sent by the same clock source of the farrow filter, obtaining interface information of the clock signal, and obtaining the clock input signal and the clock output signal according to the interface information.

Furthermore, in order to implement the above purpose, the present application also provides a filtering device of a filter, comprising:

an obtaining module, configured to obtain a clock input signal and a clock output signal input by a farrow filter;

a comparison module, configured to compare the clock input signal with the clock output signal, and determine a phase relationship between the clock input signal and the clock output signal according to a comparison result;

a determining module, configured to determine a decimal deviation factor according to the phase relationship in determining that the phase relationship meets a preset condition;

a filtering module, configured to obtain a sample input signal input by the farrow filter, and filter the sample input signal according to the decimal deviation factor to obtain a filtered sample output signal.

Furthermore, in order to implement the above purpose, the present application also provides a filter, including a memory, a processor, and a filter program of the filter stored in the memory and capable of being run on the processor, and the filter program of the filter is configured to implement steps of the filtering method of the filter as described above.

Furthermore, in order to implement the above purpose, the present application also provides a storage medium, wherein the storage medium stores a filtering program of the filter, and the filtering program of the filter is executed by the processor to implement the steps of the filtering method of a filter as described above.

The filtering method of the filter provided in the present application obtains a clock input signal and a clock output signal, compares the clock input signal and a clock output signal, and obtains a phase relationship between the clock input signal and the clock output signal, such that a decimal deviation factor can be determined according to the phase relationship when the phase relationship meets a preset condition, and the sample input signal can be adjusted according to the decimal deviation factor to obtain a smooth sample output signal. When the input data is sampled by the farrow filter, more sample output data can be obtained, thereby implementing a sample of data within high dynamic range.

### BRIEF DESCRIPTION OF THE DRAWINGS

FIG. 1 is a schematic diagram of a hardware operation environment involved in a solution of a structure of a filter according to an embodiment of the present application.

FIG. 2 is a schematic flowchart of a first embodiment of a filtering method of a filter according to the present application.

FIG. 3 is a schematic diagram of a structure of the filter of the present application.

FIG. 4 is a coordinate diagram of a phase relationship between a clock input signal and a clock output signal.

FIG. 5 is a schematic flowchart of a second embodiment of the filtering method of a filter according to the present application.

FIG. 6 is a statistical table of alignment resolutions between the clock input signal and the clock output signal of the present application.

FIG. 7 is a schematic diagram of a left-right aligned phase relationship between the clock input signal and the clock output signal of the present application.

FIG. 8 is a schematic flowchart of a third embodiment of the filtering method of a filter according to the present application.

FIG. 9 is a schematic diagram showing a filtering principle of the filter.

FIG. 10 is a statistical table of interpolation performed by the filter of the present application.

FIG. 11 is a schematic diagram of functional modules of a first embodiment of a filtering device of a filter according to the present application.

The realization of the purpose, functional characteristics, and advantages of the present application will be further described in conjunction with the embodiments and with reference to the accompanying drawings.

### DETAILED DESCRIPTION OF THE EMBODIMENTS

It should be understood that the specific embodiments described here are only used to explain the present application, and are not used to limit the present application.

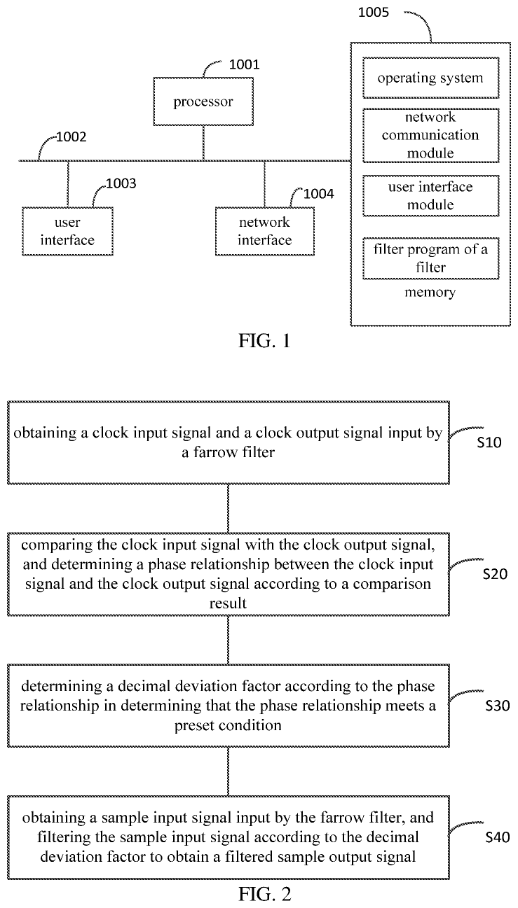

Referring to FIG. 1, FIG. 1 is a schematic diagram of the hardware operation environment involved in a solution of a structure of a filter according to an embodiment of the present application.

As shown in FIG. 1, the filter may include: a processor 1001 (such as a CPU), a communication bus 1002, a user interface 1003, a network interface 1004 and a memory 1005. The communication bus 1002 is used to implement connection and communication between these components. The user interface 1003 may include a display screen (Display) and input units such as keys. Optionally, the user interface 1003 may also include a standard wired interface and a standard wireless interface. Optionally, the network interface 1004 may include a standard wired interface and a standard wireless interface (such as a WI-FI interface). The memory 1005 may be a high-speed RAM memory, or a stable memory (non-volatile memory), such as a magnetic disk memory. Optionally, the memory 1005 may also be a storage device independent to the aforementioned processor 1001.

Those skilled in the art can understand that the structure of the filter shown in FIG. 1 does not constitute a limitation on the filter, and the filter may include more or less components than shown in the figure, or a combination of certain components, or different component arrangements.

As shown in FIG. 1, the memory 1005 as a storage medium may include an operating system, a network communication module, a user interface module, and a filter program of a filter.

In the filter shown in FIG. 1, the network interface 1004 is mainly used to connect to an external network and communicate with other network filters. The user interface 1003 is mainly used to connect with a user filter and communicate with the filter. The filter of the present application calls the filtering program of a filter stored in the memory 1005 through the processor 1001, and executes the implementation method of filtering of the filter provided in the embodiment of the present application.

Based on the above hardware structure, embodiments of a filtering method of a filter of the present application are proposed.

Referring to FIG. 2, FIG. 2 is a schematic flowchart of a first embodiment of the filtering method of a filter according to the present application.

In the first embodiment, the filtering method of a filter includes the following steps:

Step S10: obtaining a clock input signal and a clock output signal input by a farrow filter.

It should be noted that two ways are mainly used to covert a sample rate: one is to reconstruct a signal through a digital-to-analog converter, and then sample to realize the conversion of the sample rate; the other is to use a digital filter to directly perform a conversion of sampling, such as that the farrow filter realizes the conversion of the sample rate directly through digital signals.

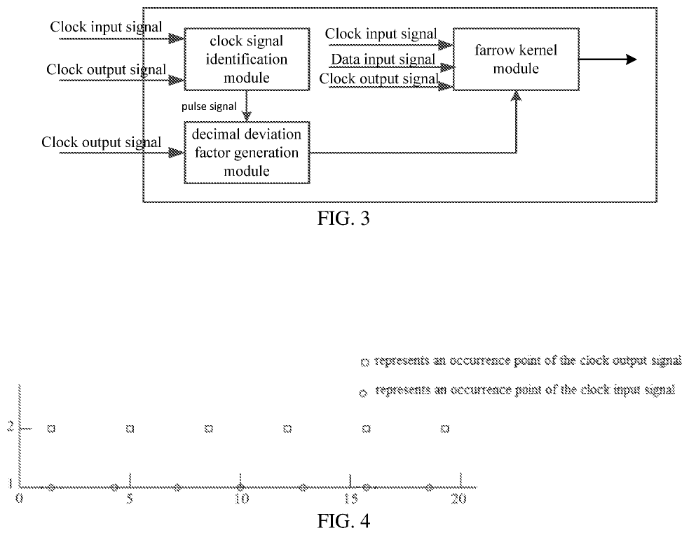

It is understandable that when sampling of data is carried out, a data signal is sampled mainly through a clock signal. In this embodiment, the farrow filter includes three modules, as shown in FIG. 3, the farrow filter mainly includes a clock signal identification module, a decimal deviation factor generation module and a farrow kernel module. The clock signal identification module is configured to receive the clock input signal and the clock output signal, identify a phase relationship between the clock input signal and clock output signal, and find a point where the clock input signal is closest to the clock output signal, so as to ensure that an accurate decimal deviation factor is generated during interpolation, which is also the basis for achieving a high dynamic range.

Step S20: comparing the clock input signal with the clock output signal, and determining a phase relationship between the clock input signal and the clock output signal according to a comparison result.

It should be noted that the phase relationship is position information of the clock input signal and the clock output signal in a corresponding sample period. For example, taking that an input sample rate is 46.875 k and an output sample rate is 48 k as an example, a frequency ratio of the clock input signal to the clock output signal is 125:128. As shown in FIG. 4, ∘ represents an occurrence point of the clock input signal, and □ represents an occurrence point of the clock output signal. From this figure, we can see that there will be a point where the phases of the clock input signal and the clock output signal are closest for every four clock output signals. From the closest point, the phase relationship of the rest of the clock points is obtained, which is also the phase relationship point of input data and output data. Therefore, when interpolation is performed by algorithms such as Lagrangian, an accurate decimal deviation factor can be obtained, thereby achieving filtering of a high dynamic range.

It can be understood that, in this embodiment, the input sample rate is 46.875 k and the output sample rate is 48 k is taken as an example, and the obtained frequency ratio of the clock input signal to the clock output signal is 125/128. It can also be realized that the input sample rate is 48 k and the output sample rate is 44.1 k, that is, an obtained period ratio of the clock input signal to the clock output signal is 147/160, and the frequency ratio of the clock input signal to the clock output signal is 160/147, so as to realize conversions of various data input signals and improve the performance of the farrow filter.

Step S30: determining a decimal deviation factor according to the phase relationship in determining that the phase relationship meets a preset condition.

In this embodiment, the preset condition is a point where the clock input signal and the clock output signal are closest, and the phase relationship between the clock input signal and the clock output signal is obtained to find a point of the clock input signal closest to the clock output signal. When the closest point appears, the decimal deviation factor generation module generates an accurate decimal deviation factor to ensure the precision of an interpolation coefficient of the interpolation filter.

It should be noted that in this embodiment, μ represents the decimal deviation factor, and μ can also represent a fractional interval. The virtual digital-to-analog change and analog filter are achieved through an interpolation method of the farrow filter, and a basic pointer of the virtual interpolation filter is obtained through the phase relationship between the input signal and the clock output signal. In this case, the basic pointer is subtracted from the phase relationship between the clock input signal and the clock output signal to obtain the decimal deviation factor, thereby realizing that the virtual interpolation filter converts the sample rate of the input data signal through interpolation.

Step S40: obtaining a sample input signal input by the farrow filter, and filtering the sample input signal according to the decimal deviation factor to obtain a filtered sample output signal.

It should be noted that the sample input signal is a sample rate of an input signal, and what pass through the farrow filter are clock signals with different sample rates, in this case, the sample input signal needs to be converted into a sample output signal that meets actual requirements. For example, an input sample rate is 46.875 k, and an output sample rate is 48 k, that is, the conversion of the sample rate from 125 to 128 or from 48 k to 44.1 k is realized.

In this embodiment, the phase relationship between the clock input signal and the clock output signal is obtained to find the closest point where the clock input signal is closest to the clock output signal. When the closest point appears, a pulse signal is output to make the decimal deviation factor generation module to generate a decimal deviation factor, and the data input signal is filtered through the accurate decimal deviation factor, so as to achieve output a data output signals within a high dynamic range.

Through the above solution, this embodiment obtains the clock input signal and the clock output signal, compares the clock input signal with the clock output signal, determines the phase relationship between the clock input signal and the clock output signal, obtains an accurate decimal deviation factor in determining that the phase relationship meets a preset condition, and adjusts the sample input signal according to the decimal deviation factor to obtain a smooth sample output signal. When the input data is sampled through the farrow filter, more sample output data can be obtained to realize sample of data input signal within a high dynamic range.

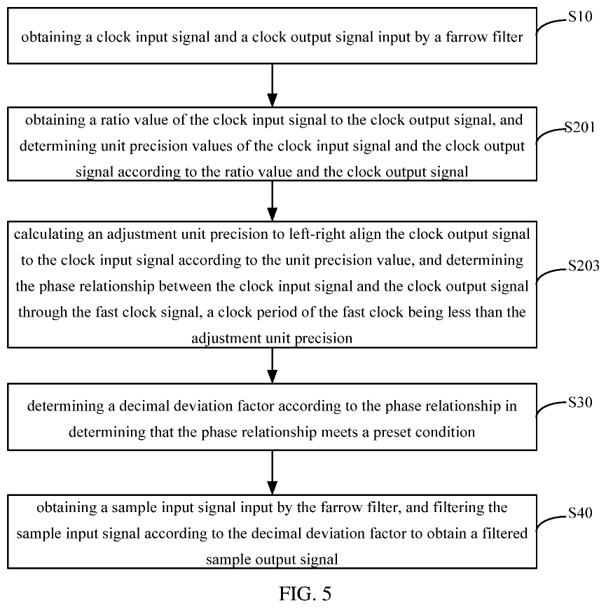

Further, as shown in FIG. 5, a second embodiment of a filtering method of a filter of the present application is provided based on the first embodiment. In this embodiment, the step S20 includes:

Step S201: obtaining a ratio value of the clock input signal to the clock output signal, and determining unit precision values of the clock input signal and the clock output signal according to the ratio value and the clock output signal.

In this embodiment, taking that the clock input signal is 46.875 k and the clock output signal is 48 k as an example for illustration, the frequency ratio of the clock input signal to the clock output signal is 125/128. Therefore, for the clock output signal, the clock output signal is subdivided into 1/128, and the phase relationship between the clock input signal and the clock output signal can be accurately obtained. In addition, when a clock input signal of 187.5 k is converted to a clock output signal of 192 k, a frequency ratio of the clock input signal and the clock output signal is 125/128. Therefore, for the clock output signal, the frequency ratio is subdivided into 1/128, or to a higher degree of subdivision, which is not limited in this embodiment, the phase relationship between the clock input signal and the clock output signal can be accurately obtained.

It should be noted that in this embodiment, an unit precision value is equal to a time period of a minimum resolution frequency, indicating a minimum resolution frequency of the clock input signal aligning with the clock output signal. The minimum resolution frequency is ensured and associated with the clock alignment module to get a better alignment effect. For example, when the clock input signal is 48 k and the clock output signal is 44.1 k, the frequency ratio of the clock input signal to the clock output signal is 160/147, and the obtained minimum resolution frequency is 44.1*2*160 or 48*2*147. When the clock input signal is 46.875 k and the clock output signal is 48 k, the frequency ratio of the clock input signal to the clock output signal is 125/128, and the obtained minimum resolution frequency is 46.875*2*128 or 48*2*125, thereby a better alignment effect can be obtained.

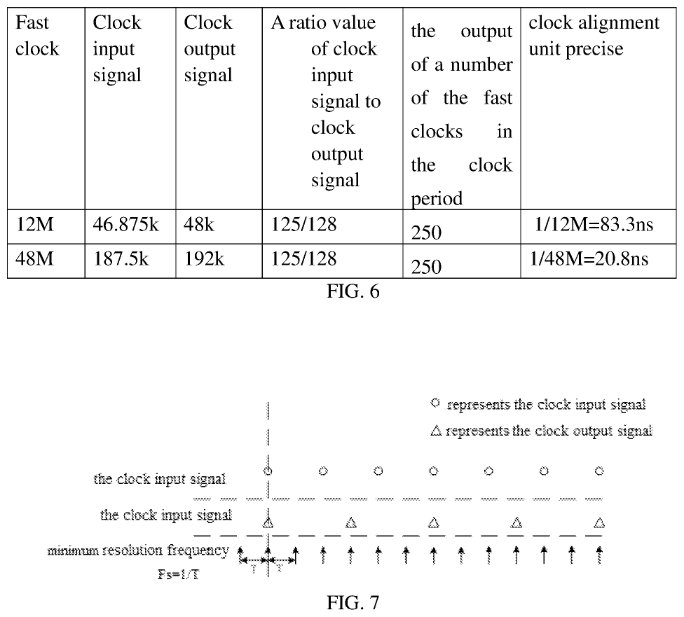

As shown in FIG. 6, through putting a fast clock signal, when the clock input signal is 46.875 k and the clock output signal is 48 k, the frequency ratio of the clock input signal to the clock output signal is 125/128, and the minimum resolution frequency is calculated as 46.875*128*2=12M or 48*125*2=12M, the clock alignment information of that the clock input signal is 46.875 k and the clock output signal is 48 k is obtained. When the clock input signal is 187.5 k, and the clock output signal is 192 k, the frequency ratio of the clock input signal and the clock output signal is 125/128, it is obtained that the minimum resolution frequency is 187.5*128*2=48M or 192*125*2=48M, the minimum resolution frequency can be the minimum alignment clock, which can be used as sample clocks of a fast clock and a slow clock in the clock alignment module.

It should be noted that when the clock input signal is 48 k and the clock output signal is 44.1 k, due to the frequency ratio of the clock input signal to the clock output signal is 160/147, in this case, the clock input signal is greater than the clock output signal, by calculating the proportional relationship between the clock output signal and the clock input signal, each data sequence can be obtained, and a use range of the farrow filter can be expanded, so as to achieve the purpose of improving the performance of the farrow filter.

It should be noted that in this embodiment, a preset clock signal is obtained, the clock input signal is compared with the clock output signal according to the preset clock signal, and the ratio value of the clock input signal to clock output signal is obtained according to the comparison result. The preset clock signal may be a fast clock signal, and a fast clock is used to compare the phase of the clock input signal with that of the clock output signal. For example, the fast clock is 12M, if the input clock is 46.875 k and the output clock is 48 k, then the frequency ratio of the clock input signal to the clock output signal is 125/128, and the corresponding minimum resolution clock is 12M. For an output clock of 48 k, there are 250 fast clock periods corresponding to one clock output signal clock, that is, fast clock/output clock which is the frequency ratio of the fast clock to the output clock is 12M/48 k=250.

Step S202: determining a phase relationship between the clock input signal and the clock output signal according to the unit precision values.

It should be noted that because the phase relationship between the two clocks can be regarded as one clock being fixed, and the other clock being left or right shifted, thereby the phase relationship between the clock input signal and the clock output signal can be obtained.

Further, the step S202 includes:

Step S203: calculating an adjustment unit precision to left-right align the clock output signal to the clock input signal according to the unit precision value, and determining the phase relationship between the clock input signal and the clock output signal through the fast clock signal, a clock period of the fast clock being less than the adjustment unit precision.

In this embodiment, for 46.875→48 or 187.5 k→192 k, the phase relationship between the two clocks will continuously change, but in the fast clock domain, periodicity appears every 128 clock periods. In the slow clock domain, periodicity appears every 125 clock periods, as shown in FIG. 7. Because it may be left or right shift, the clock alignment module needs to check whether there are left shift and right shift. The minimum resolution frequency is used as the sample clocks of the fast clock and the slow clock in the clock alignment module. The minimum resolution frequency is twice the least common multiple of the input clock signal and the output clock signal in the alignment module. The resolution frequency is set to be greater than or equal to the minimum resolution frequency, which can ensure that the phases of the two clocks are completely aligned. F_{S} represents the minimum resolution frequency, T represents the minimum resolution clock period, F_{S}=1/T.

The solution provided in this embodiment obtains the ratio value of the clock input signal to the clock output signal by putting a fast clock signal, and then obtains the unit precision value of the clock output signal, so that another clock signal is detected within the unit precision value, thereby determining the accurate positions of the clock input signal and the clock output signal, and realizing more accurately detection of the clock input signal and the clock output signal.

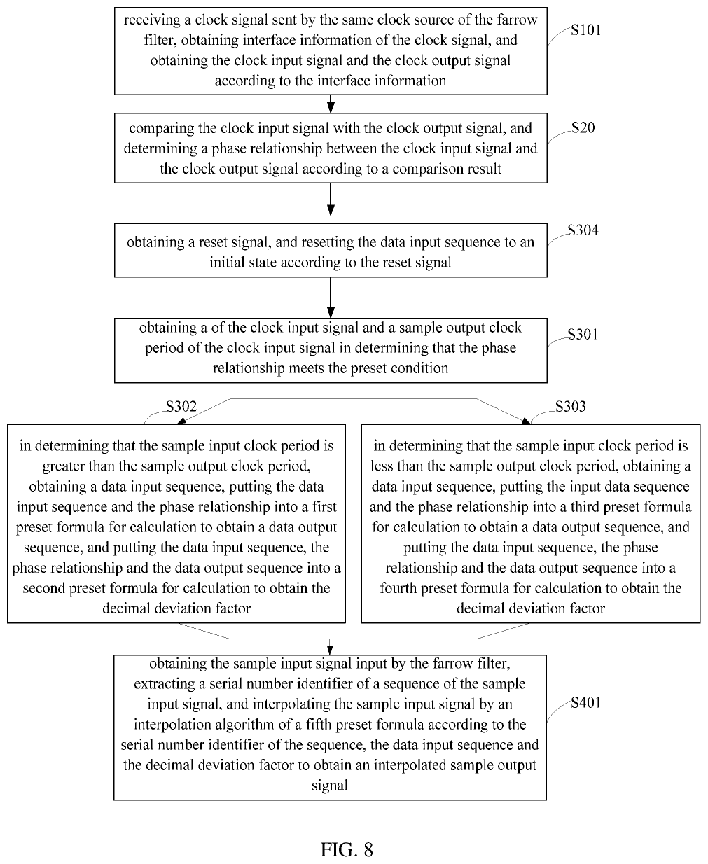

Further, as shown in FIG. 8, a third embodiment of the filtering method of the filter of the present application is provided based on the first embodiment or the second embodiment.

In this embodiment, the illustration is based on the first embodiment, and step S30 includes:

Step S301: obtaining a of the clock input signal and a sample output clock period of the clock input signal in determining that the phase relationship meets the preset condition.

Step S302, in determining that the sample input clock period is greater than the sample output clock period, obtaining a data input sequence, putting the data input sequence and the phase relationship into a first preset formula for calculation to obtain a data output sequence, and putting the data input sequence, the phase relationship and the data output sequence into a second preset formula for calculation to obtain the decimal deviation factor.

Step S303: in determining that the sample input clock period is less than the sample output clock period, obtaining a data input sequence, putting the input data sequence and the phase relationship into a third preset formula for calculation to obtain a data output sequence, and putting the data input sequence, the phase relationship and the data output sequence into a fourth preset formula for calculation to obtain the decimal deviation factor.

The first preset formula is:

mₖ=int[k*Tₒ/Tᵢ];

k represents the data input sequence, Tₒ/Tᵢ represents the phase relationship, mₖ represents the data output sequence;

The second preset formula is:

μ=k*Tₒ/Tᵢ−mₖ;

μ represents the decimal deviation factor;

The third preset formula is:

mₖ=int[k*Tᵢ/Tₒ], Tᵢ/Tₒrepresents the phase relationship;

The fourth preset formula is:

μ=k*Tᵢ/Tₒ−mₖ.

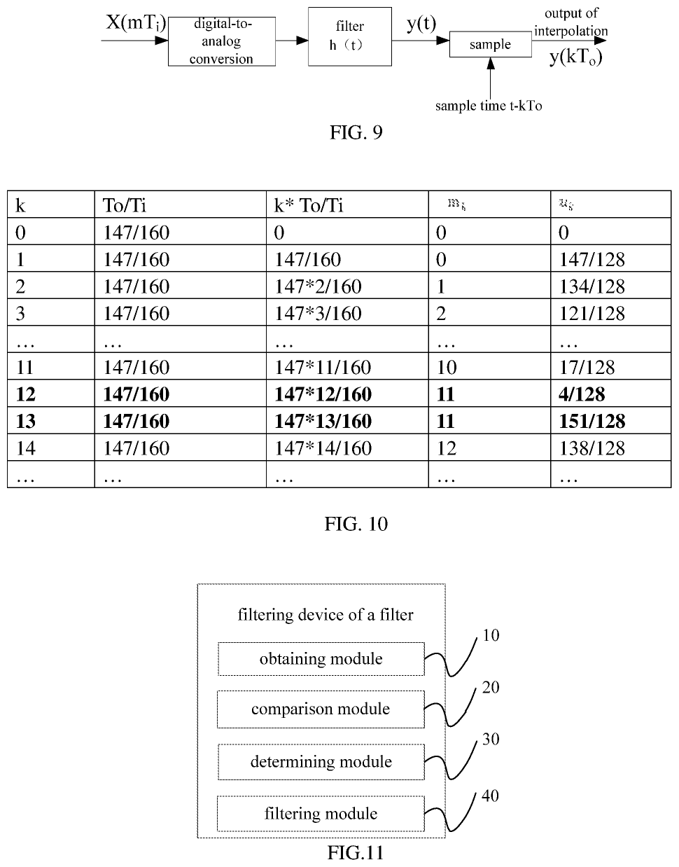

As shown in FIG. 9, assuming that the input sample sequence is x(m) and the interpolation filter is h(t), the output of the filter in the clock input signal domain is:

yᵢ(t)=Σₘ₌₀^{M}x(mᵢ)*h(t−mTᵢ);

Tᵢ represents a sample period of a receiver, y(t) represents an output signal of a signal value after digital-to-analog conversion and analog filter h(t), and M represents a number of the interpolation filters;

y(t) is resampled at a time t=kTₒ, an output value after interpolation is:

y(kTₒ)=Σₘ₌₀^{M}x(m)*h(kT_{O}−mTᵢ)

the output sequence k, according to mₖ=int[k*Tₒ/Tᵢ], μ=k*Tₒ/Tᵢ−mₖ P=int[k*Tₒ/Tᵢ]−m, it can be obtained:

$$\begin{matrix}y ( {kT}_{o} ) = {\sum }_{p = 0}^{p} x ( int [ k * \frac{{T}_{o}}{{T}_{i}} - p ] ) * \\ h ( {kT}_{o} = ( int [ k * \frac{{T}_{O}}{{T}_{i}} ] + p ) {T}_{i} ) \\ = {\sum }_{p = 0}^{p} x ( {m}_{k} - p ) * h ( {kT}_{o} - ( {m}_{k} - p ) {T}_{i} ) \\ = {\sum }_{p = 0}^{p} x ( {m}_{k} - p ) * h ( ( p + {μ}_{k} ) {T}_{i} ) ;\end{matrix}$$

p represents the newly collected data signal, due to hₐ(t)=Σₙ₌₀^{N-1}Σₘ₌₀^{M}cₘ(n)fₘ(n, t);

that is, hₐ((p+μₖ)Tᵢ)=Σₙ₌₀^{N-1}Σₘ₌₀^{M}cₘ(n)fₘ)(n, (p+μₖ)Tᵢ);

therefore, y(kTₒ)=Σₚ₌₀^{p}x(mₖ−p)*Σₙ₌₀^{N}Σₘ₌₀^{M}cₘ(n)fₘ(n, (p+μₖ)Tᵢ).

Based on this formula, various forms of farrow filters can be obtained, such as classic farrow filters and transposed farrow filters, etc. For example, fₘ(n, t) can be constructed to be, for example, μₖ^{m}, (2μₖ−1)^{m}, (1−2μₖ)^{m}, etc. When M=4−1, for μₖ^{m}, there are 1, μₖ¹, μₖ² and μₖ³, the decimal deviation factor generation module can be used to generate dynamic μₖ¹, μₖ², μₖ³.

As shown in FIG. 10, when k is an input collection sequence and when the ratio value of the clock output period to the clock input period is 147/140, k*To/Ti produces 0, 147/160, 147*2/160, etc. Correspondingly. That is, mₖ is 0, 0, 1, etc. correspondingly, and the μₖ is 0, 147/128, 134/128, etc. correspondingly. When k=12, 13, mₖ is the same. Therefore, the calculation of μₖ must be accurate, otherwise distortion will occur, μₖ depends on whether the closest phase relationship between the two clocks can be accurately found. At the time when the μₖ is initialized to a specific value, there should be two or more fast clock pulses between two slow clocks.

Further, step S40 includes:

Step S401: obtaining the sample input signal input by the farrow filter, extracting a serial number identifier of a sequence of the sample input signal, and interpolating the sample input signal by an interpolation algorithm of a fifth preset formula according to the serial number identifier of the sequence, the data input sequence and the decimal deviation factor to obtain an interpolated sample output signal.

The fifth preset formula is:

$$P ( n ) = [ k ( n - ( - 1 ) ) k ( n - 0 ) k ( n - 1 ) k ( n - 2 ) ] * \vert \begin{matrix}- \frac{1}{6} & \frac{1}{2} & - \frac{1}{3} & 0 \\ \frac{1}{2} & - 1 & - \frac{1}{2} & 1 \\ - \frac{1}{2} & \frac{1}{2} & 1 & 0 \\ \frac{1}{6} & 0 & - \frac{1}{6} & 0\end{matrix} \vert * {[ {μ}^{3} {μ}^{2} μ 1 ]}^{′} ;$$

P(n) represents the sample output signal, and n represents a serial number identifier of a current input sequence of the farrow filter.

It should be noted that in this embodiment, the Lagrangian interpolation formula is used:

[symbol]

(x)=(x−x₋₁)(x−x₀)(x−x₁)(x−x₂);

x represents a serial number of a small table corresponding to a missing value, [symbol] (x) represents an interpolation result of the missing value. After setting x to be −1, 0, 1, and 2, it can produce:

$$ℓ ( - 1 ) ( x ) = \frac{( x - 0 ) ( x - 1 ) ( x - 2 )}{( - 1 - 1 ) ( - 1 - 0 ) ( - 1 - 2 )} = - 1 / 6 {x}^{3} + 1 / 2 {x}^{2} - 1 / 3 x + 0 ;$$

$$ℓ ( 0 ) ( x ) = \frac{( x + 1 ) ( x - 1 ) ( x - 2 )}{( 0 - 1 ) ( 0 - 1 ) ( 0 - 2 )} = - 1 / 2 {x}^{3} - {x}^{2} - 1 / 2 x + 1 ;$$

$$ℓ ( 1 ) ( x ) = \frac{( x + 1 ) ( x - 0 ) ( x - 2 )}{( 1 + 1 ) ( 1 - 0 ) ( 1 - 2 )} = - 1 / 2 {x}^{3} + 1 / 2 {x}^{2} + 1 x + 0 ;$$

$$ℓ ( 2 ) ( x ) = \frac{( x + 1 ) ( x - 0 ) ( x - 1 )}{( 2 + 1 ) ( 2 - 0 ) ( 2 - 1 )} = 1 / 6 {x}^{3} + 0 - 1 / 6 x + 0 ;$$

Due to P(x)=[y(−1) y0 y1 y2]*[ [symbol] (−1)(x) [symbol] 0(x) [symbol] 1(x) [symbol] 2(x)],

P(x) represents the newly collected data information, and y represents the data input sequence. After [symbol] (−1)(x), [symbol] (0)(x), [symbol] (1)(x) and [symbol] 2(x) are input to the former formula, it produces:

$$\begin{matrix}P ( x ) = [ y ( - 1 ) y 0 y 1 y 2 ] * {[ ℓ ( - 1 ) ( x ) ℓ0 ( x ) ℓ 1 ( x ) ℓ 2 ( x ) ]}^{′} \\ = [ y ( - 1 ) y 0 y 1 y 2 ] * \\ \vert \begin{matrix}- \frac{1}{6} & \frac{1}{2} & - \frac{1}{3} & 0 \\ \frac{1}{2} & - 1 & - \frac{1}{2} & 1 \\ - \frac{1}{2} & \frac{1}{2} & 1 & 0 \\ \frac{1}{6} & 0 & - \frac{1}{6} & 0\end{matrix} \vert * {[ {x}^{3} {x}^{2} x 1 ]}^{′} ;\end{matrix}$$

y is converted to be a data input sequence k, and x is converted to be the decimal deviation factor μ, so that:

$$P ( n ) = [ k ( n - ( - 1 ) ) k ( n - 0 ) k ( n - 1 ) k ( n - 2 ) ] * \vert \begin{matrix}- \frac{1}{6} & \frac{1}{2} & - \frac{1}{3} & 0 \\ \frac{1}{2} & - 1 & - \frac{1}{2} & 1 \\ - \frac{1}{2} & \frac{1}{2} & 1 & 0 \\ \frac{1}{6} & 0 & - \frac{1}{6} & 0\end{matrix} \vert * {[ {μ}^{3} {μ}^{2} μ 1 ]}^{′} ;$$

In this way, the sample input signal is valuated by interpolation to obtain the sample output signal, so as to realize filtering through specific rules.

It should be noted that in this embodiment, interpolation is performed by the

Lagrangian interpolation, and valuation of interpolation can also be performed by other interpolation methods, which is not limited in this embodiment.

Further, before the step S30, the method further includes:

Step S304: obtaining a reset signal, and resetting the data input sequence to an initial state according to the reset signal.

It should be noted that when the closest point where the clock input signal is closest to the clock output signal is detected, the decimal deviation factor is generated, and the decimal deviation factor generation module is initialized to a specific value, thereby avoiding a deviation of the data input sequence to cause the imprecision of the decimal deviation factor, improving the precision of the decimal deviation factor, and determining the output of a high dynamic sample output signal.

Further, step S10 includes:

Step S101: receiving a clock signal sent by the same clock source of the farrow filter, obtaining interface information of the clock signal, and obtaining the clock input signal and the clock output signal according to the interface information.

In this embodiment, if the clock input signal and the clock output signal have jitter or drift completely independent to each other, it will affect the precision of clock alignment. Therefore, the clock sources of the clock input signal and the clock output signal are set to be the same clock source.

The solution provided by this embodiment conducts conversion of the frequency ratios 125/128 and 160/147 of the clock input signal to the clock output signal, thereby expanding the performance of the farrow filter, and filters the collected input signal by the interpolation filter using the accurate decimal deviation factor to obtain the interpolation estimation of the collected output signal in a specific range, thereby realizing filtering of a high dynamic range.

The present application further provides a filtering device of the filter.

Referring to FIG. 9, FIG. 9 is a schematic diagram of functional modules of the first embodiment of the filtering device of the filter of the present application.

In the first embodiment of the filtering device of the filter of the present application, the filtering device of the filter includes:

an obtaining module 10 is configured to obtain a clock input signal and a clock output signal input by a farrow filter.

It should be noted that two ways are mainly used to covert a sample rate: one is to reconstruct a signal through a digital-to-analog converter, and then sample to realize the conversion of the sample rate; the other is to use a digital filter to directly perform a conversion of sampling, such as that the farrow filter realizes the conversion of the sample rate directly through digital signals.

It is understandable that when sampling of data is carried out, a data signal is sampled mainly through a clock signal. In this embodiment, the farrow filter includes three modules, as shown in FIG. 3, the farrow filter mainly includes a clock signal identification module, a decimal deviation factor generation module and a farrow kernel module. The clock signal identification module is configured to receive the clock input signal and the clock output signal, identify a phase relationship between the clock input signal and clock output signal, and find a point where the clock input signal is closest to the clock output signal, so as to ensure that an accurate decimal deviation factor is generated during interpolation, which is also the basis for achieving a high dynamic range.

A comparison module 20 is configured to compare the clock input signal with the clock output signal, and determine a phase relationship between the clock input signal and the clock output signal according to a comparison result.

It should be noted that the phase relationship is position information of the clock input signal and the clock output signal in a corresponding sample period. For example, taking that an input sample rate is 46.875 k and an output sample rate is 48 k as an example, a frequency ratio of the clock input signal to the clock output signal is 125:128. As shown in FIG. 4, ∘ represents an occurrence point of the clock input signal, and □ represents an occurrence point of the clock output signal. From this figure, we can see that there will be a point where the phases of the clock input signal and the clock output signal are closest for every four clock output signals. From the closest point, the phase relationship of the rest of the clock points is obtained, which is also the phase relationship point of input data and output data. Therefore, when interpolation is performed by algorithms such as Lagrangian, an accurate decimal deviation factor can be obtained, thereby achieving filtering of a high dynamic range.

It can be understood that, in this embodiment, the input sample rate is 46.875 k and the output sample rate is 48 k is taken as an example, and the obtained frequency ratio of the clock input signal to the clock output signal is 125/128. It can also be realized that the input sample rate is 48 k and the output sample rate is 44.1 k, that is, an obtained period ratio of the clock input signal to the clock output signal is 147/160, and the frequency ratio of the clock input signal to the clock output signal is 160/147, so as to realize conversions of various data input signals and improve the performance of the farrow filter.

A determining module 30 is configured to determine a decimal deviation factor according to the phase relationship in determining that the phase relationship meets a preset condition.

In this embodiment, the preset condition is a point where the clock input signal and the clock output signal are closest, and the phase relationship between the clock input signal and the clock output signal is obtained to find a point of the clock input signal closest to the clock output signal. When the closest point appears, the decimal deviation factor generation module generates an accurate decimal deviation factor to ensure the precision of an interpolation coefficient of the interpolation filter.

It should be noted that in this embodiment, μ represents the decimal deviation factor, and μ can also represent a fractional interval. The virtual digital-to-analog change and analog filter are achieved through an interpolation method of the farrow filter, and a basic pointer of the virtual interpolation filter is obtained through the phase relationship between the input signal and the clock output signal. In this case, the basic pointer is subtracted from the phase relationship between the clock input signal and the clock output signal to obtain the decimal deviation factor, thereby realizing that the virtual interpolation filter converts the sample rate of the input data signal through interpolation.

A filtering module 40 is configured to obtain a sample input signal input by the farrow filter, and filter the sample input signal according to the decimal deviation factor to obtain a filtered sample output signal.

It should be noted that the sample input signal is a sample rate of an input signal, and what pass through the farrow filter are clock signals with different sample rates, in this case, the sample input signal needs to be converted into a sample output signal that meets actual requirements. For example, an input sample rate is 46.875 k, and an output sample rate is 48 k, that is, the conversion of the sample rate from 125 to 128 or from 48 k to 44.1 k is realized.

In this embodiment, the phase relationship between the clock input signal and the clock output signal is obtained to find the closest point where the clock input signal is closest to the clock output signal. When the closest point appears, a pulse signal is output to make the decimal deviation factor generation module to generate a decimal deviation factor, and the data input signal is filtered through the accurate decimal deviation factor, so as to achieve output a data output signals within a high dynamic range.

Through the above solution, this embodiment obtains the clock input signal and the clock output signal, compares the clock input signal with the clock output signal, determines the phase relationship between the clock input signal and the clock output signal, obtains an accurate decimal deviation factor in determining that the phase relationship meets a preset condition, and adjusts the sample input signal according to the decimal deviation factor to obtain a smooth sample output signal. When the input data is sampled through the farrow filter, more sample output data can be obtained to realize sample of data within a high dynamic range.

Furthermore, in order to implement the above purpose, the present application also provides a filter, including a memory, a processor, and a filter program of the filter stored in the memory and capable of being run on the processor, and the filter program of the filter is configured to implement steps of the filtering method of the filter as described above.

Furthermore, in order to implement the above purpose, the present application also provides a storage medium, wherein the storage medium stores a filtering program of the filter, and the filtering program of the filter is executed by the processor to implement the steps of the filtering method of a filter as described above.

It should be noted that herein, the terms “comprise”, “include” or any other variants thereof are intended to cover non-exclusive inclusion, so that a process, method, article or device including a series of elements not only includes those elements, but also includes other elements that are not explicitly listed, or elements inherent to the process, method, article, or device. If there are no more limitation, the element defined by the sentence “including a . . . ” does not exclude the existence of other same elements in the process, method, article, or device that includes the element.

The serial numbers of the foregoing embodiments of the present application are only for description, and do not represent the superiority or inferiority of the embodiments.

Through the description of the above embodiments, those skilled in the art can clearly understand that the method of the above embodiments can be implemented by means of software plus the necessary general hardware platform. Of course, it can also be implemented by hardware, but in many cases the former is better embodiment. Based on this understanding, the technical solution of the present application essentially or the part that contributes to the prior art can be embodied in the form of a software product, and the computer software product is stored in a computer-readable storage medium as described above (such as ROM/RAM, magnetic disk, optical disk), including several instructions to make a smart terminal device (can be a mobile phone, computer, terminal device, air conditioner, or network terminal device, etc.) to execute the method described at the various embodiments of the present application.

The above are only preferred embodiments of the present application, and do not limit the scope of the present application. Any equivalent structure or equivalent process transformation made using the content of the description and drawings of the present application, or directly or indirectly used in other related technical fields are all included in the scope of patent protection of the present application.

What is claimed is:

1. A filtering method of a filter, comprising:
obtaining a clock input signal and a clock output signal input by a farrow filter;
comparing the clock input signal with the clock output signal, and determining a phase relationship between the clock input signal and the clock output signal according to a comparison result;
determining a decimal deviation factor according to the phase relationship in determining that the phase relationship meets a preset condition; and
obtaining a sample input signal input by the farrow filter, and filtering the sample input signal according to the decimal deviation factor to obtain a filtered sample output signal.

2. The filtering method according to claim 1, wherein the comparing the clock input signal with the clock output signal, and determining a phase relationship between the clock input signal and the clock output signal according to a comparison result comprises:
obtaining a ratio value of the clock input signal to the clock output signal, and determining unit precision values of the clock input signal and the clock output signal according to the ratio value and the clock output signal; and
determining the phase relationship between the clock input signal and the clock output signal according to the unit precision values.

3. The filtering method according to claim 2, wherein the determining the phase relationship between the clock input signal and the clock output signal according to the unit precision values comprises:
calculating an adjustment unit precision to left-right align the clock output signal to the clock input signal according to the unit precision values, and determining the phase relationship between the clock input signal and the clock output signal through a fast clock signal, a clock period of the fast clock being less than the adjustment unit precision.

4. The filtering method according to claim 1, wherein the determining a decimal deviation factor according to the phase relationship in determining that the phase relationship meets a preset condition comprises:
obtaining a sample input clock period of the clock input signal and a sample output clock period of the clock input signal in determining that the phase relationship meets the preset condition;
in determining that the sample input clock period is greater than the sample output clock period, obtaining a data input sequence, putting the data input sequence and the phase relationship into a first preset formula for calculation to obtain a data output sequence, and putting the data input sequence, the phase relationship and the data output sequence into a second preset formula for calculation to obtain the decimal deviation factor; or
in determining that the sample input clock period is less than the sample output clock period, obtaining a data input sequence, putting the input data sequence and the phase relationship into a third preset formula for calculation to obtain a data output sequence, and putting the data input sequence, the phase relationship and the data output sequence into a fourth preset formula for calculation to obtain the decimal deviation factor;
wherein, the first preset formula is:
mₖ=int[k*Tₒ/Tᵢ];
k represents the data input sequence, Tₒ/Tᵢ represents the phase relationship, mₖ represents the data output sequence;
the second preset formula is:
μ=k*Tₒ/Tᵢ−mₖ;
μ represents the decimal deviation factor;
the third preset formula is:
mₖ=int[k*Tᵢ/Tₒ], Tᵢ/Tₒ represents the phase relationship;
the fourth preset formula is:
μ=k*Tᵢ/Tₒ−mₖ.

5. The filtering method according to claim 4, wherein the obtaining a sample input signal input by the farrow filter, and filtering the sample input signal according to the decimal deviation factor to obtain a filtered sample output signal comprises:
obtaining the sample input signal input by the farrow filter, extracting a serial number identifier of a sequence in the sample input signal, and interpolating the sample input signal by an interpolation algorithm of a fifth preset formula according to the serial number identifier of the sequence, the data input sequence and the decimal deviation factor to obtain the sample output signal after being interpolated;
wherein, the fifth preset formula is:
$$P ( n ) = [ k ( n - ( - 1 ) ) k ( n - 0 ) k ( n - 1 ) k ( n - 2 ) ] * \vert \begin{matrix}- \frac{1}{6} & \frac{1}{2} & - \frac{1}{3} & 0 \\ \frac{1}{2} & - 1 & - \frac{1}{2} & 1 \\ - \frac{1}{2} & \frac{1}{2} & 1 & 0 \\ \frac{1}{6} & 0 & - \frac{1}{6} & 0\end{matrix} \vert * {[ {μ}^{3} {μ}^{2} μ 1 ]}^{′} ;$$
P(n) represents the sample output signal, and n represents a serial number identifier of a current input sequence of the farrow filter.

6. The filtering method according to claim 5, wherein subsequent to determining a decimal deviation factor according to the phase relationship in determining that the phase relationship meets a preset condition, the method further comprises:
obtaining a reset signal, and resetting the data input sequence to an initial state according to the reset signal.

7. The filtering method according to claim 1, wherein the obtaining a clock input signal and a clock output signal comprises:
receiving a clock signal sent by a clock source of the farrow filter, obtaining interface information of the clock signal, and obtaining the clock input signal and the clock output signal according to the interface information.

8. A filtering device of a filter, comprising:
an obtaining module, configured to obtain a clock input signal and a clock output signal input by the farrow filter;
a comparison module, configured to compare the clock input signal with the clock output signal, and determine a phase relationship between the clock input signal and the clock output signal according to a comparison result;
a determining module, configured to determine a decimal deviation factor according to the phase relationship in determining that the phase relationship meets a preset condition; and
a filtering module, configured to obtain a sample input signal input by the farrow filter, and filter the sample input signal according to the decimal deviation factor to obtain a filtered sample output signal.

9. A filter, comprising a memory, a processor, and a filter program of the filter stored in the memory and capable of being run on the processor, and the filter program of the filter is configured to implement steps of the filtering method of the filter as below:
obtaining a clock input signal and a clock output signal input by a farrow filter;
comparing the clock input signal with the clock output signal, and determining a phase relationship between the clock input signal and the clock output signal according to a comparison result;
determining a decimal deviation factor according to the phase relationship in determining that the phase relationship meets a preset condition; and
obtaining a sample input signal input by the farrow filter, and filtering the sample input signal according to the decimal deviation factor to obtain a filtered sample output signal.

10. The filter according to claim 9, wherein the comparing the clock input signal with the clock output signal, and determining a phase relationship between the clock input signal and the clock output signal according to a comparison result comprises:
obtaining a ratio value of the clock input signal to the clock output signal, and determining unit precision values of the clock input signal and the clock output signal according to the ratio value and the clock output signal; and
determining the phase relationship between the clock input signal and the clock output signal according to the unit precision values.

11. The filter according to claim 10, wherein the determining the phase relationship between the clock input signal and the clock output signal according to the unit precision value comprises:
calculating an adjustment unit precision to left-right align the clock output signal to the clock input signal according to the unit precision values, and determining the phase relationship between the clock input signal and the clock output signal through a fast clock signal, a clock period of the fast clock being less than the adjustment unit precision.

12. The filter according to claim 9, wherein the determining a decimal deviation factor according to the phase relationship in determining that the phase relationship meets a preset condition comprises:
obtaining a sample input clock period of the clock input signal and a sample output clock period of the clock input signal in determining that the phase relationship meets the preset condition;
in determining that the sample input clock period is greater than the sample output clock period, obtaining a data input sequence, putting the data input sequence and the phase relationship into a first preset formula for calculation to obtain a data output sequence, and putting the data input sequence, the phase relationship and the data output sequence into a second preset formula for calculation to obtain the decimal deviation factor; or
in determining that the sample input clock period is less than the sample output clock period, obtaining a data input sequence, putting the input data sequence and the phase relationship into a third preset formula for calculation to obtain a data output sequence, and putting the data input sequence, the phase relationship and the data output sequence into a fourth preset formula for calculation to obtain the decimal deviation factor;
wherein, the first preset formula is:
mₖ=int[k*Tₒ/Tᵢ];
k represents the data input sequence, Tₒ/Tᵢ represents the phase relationship, mₖ represents the data output sequence;
the second preset formula is:
μ=k*Tₒ/Tᵢ−mₖ;
μ represents the decimal deviation factor;
the third preset formula is:
mₖ=int[k*Tᵢ/Tₒ]; Tᵢ/Tₒ represents the phase relationship;
the fourth preset formula is:
μ=k*Tᵢ/Tₒ−mₖ.

13. The filter according to claim 12, wherein the obtaining a sample input signal input by the farrow filter, and filtering the sample input signal according to the decimal deviation factor to obtain a filtered sample output signal comprises:
obtaining the sample input signal input by the farrow filter, extracting a serial number identifier of a sequence in the sample input signal, and interpolating the sample input signal by an interpolation algorithm of a fifth preset formula according to the serial number identifier of the sequence, the data input sequence and the decimal deviation factor to obtain the sample output signal after being interpolated;
wherein, the fifth preset formula is:
$$P ( n ) = [ k ( n - ( - 1 ) ) k ( n - 0 ) k ( n - 1 ) k ( n - 2 ) ] * \vert \begin{matrix}- \frac{1}{6} & \frac{1}{2} & - \frac{1}{3} & 0 \\ \frac{1}{2} & - 1 & - \frac{1}{2} & 1 \\ - \frac{1}{2} & \frac{1}{2} & 1 & 0 \\ \frac{1}{6} & 0 & - \frac{1}{6} & 0\end{matrix} \vert * {[ {μ}^{3} {μ}^{2} μ 1 ]}^{′} ;$$
P(n) represents the sample output signal, and n represents a serial number identifier of a current input sequence of the farrow filter.

14. The filter according to claim 13, wherein subsequent to in determining a decimal deviation factor according to the phase relationship in determining that the phase relationship meets a preset condition, the filtering method further comprises:
obtaining a reset signal, and resetting the data input sequence to an initial state according to the reset signal.

15. The filter according to claim 9, wherein the obtaining a clock input signal and a clock output signal comprises:
receiving a clock signal sent by a clock source of the farrow filter, obtaining interface information of the clock signal, and obtaining the clock input signal and the clock output signal according to the interface information.
